(19) United States
(12) Patent Application Publication
(10) Pub. No.: US 2014/0127625 A1
(43) Pub. Date: May 8, 2014

(54) ORTHOGONAL SOLVENTS AND COMPATIBLE PHOTORESISTS FOR THE PHOTOLITHOGRAPHIC PATTERNING OF ORGANIC ELECTRONIC DEVICES

(71) Applicants: John Defranco, Ithaca, NY (US); Charles Warren Wright, Fairport, NY (US)

(72) Inventors: John Defranco, Ithaca, NY (US); Charles Warren Wright, Fairport, NY (US)

(73) Assignee: ORTHOGONAL, INC., Ithaca, NY (US)

(21) Appl. No.: 14/113,408

(22) PCT Filed: Apr. 24, 2012
(86) PCT No.: PCT/US12/34748

§ 371 Date: Jan. 3, 2014

Related U.S. Application Data
(60) Provisional application No. 61/478,627, filed on Apr. 25, 2011.

(51) Int. Cl. G03F 7/038

(52) U.S. Cl. CPC G03F 7/038
USPC 430/270.1; 430/325

(57) ABSTRACT

The present invention provides improved solvents and photoresists for the photolithographic patterning of organic electronic devices, systems comprising combinations of these solvents and photoresists, and methods for using these systems of solvents and photoresists to pattern various organic electronic materials.

This application is being filed on 24 Apr. 2012, as a PCT International Patent application in the name of Orthogonal, Inc., a U.S. national corporation, applicant for the designation of all countries except the U.S., and, John DeFranco, a citizen of the U.S., and Charles Warren Wright, a citizen of the U.S., applicants for the designation of the U.S. only, and claims priority to U.S. patent application Ser. No. 61/478,627 filed on 25 Apr. 2011, the disclosure of which is incorporated herein by reference in its entirety.

### FIELD OF THE INVENTION

The present invention provides improved solvents and photoresists for the photolithographic patterning of organic electronic devices, systems comprising combinations of these solvents and photoresists, and methods for using these systems of solvents and photoresists to pattern various organic electronic materials.

### BACKGROUND OF THE INVENTION

Because organic (i.e., carbon-based) electronic devices offer significant performance and price advantages relative to conventional inorganic-based devices, there has been much commercial interest in the use of organic materials in electronic device fabrication. Specifically, organic materials such as conductive polymers can be used to manufacture devices that have reduced weight and drastically greater mechanical flexibility compared to conventional electronic devices based on metals and silicon. Equally as important, devices based on organic materials are likely to be significantly less damaging to the environment than devices made with inorganic materials, since organic materials do not require toxic metals and can ideally be fabricated using relatively benign solvents and methods of manufacture. Thus in light of these superior weight and mechanical properties and particularly in light of the lowered environmental impact in fabrication and additionally in disposal, electronic devices based on organic materials are expected to be less expensive than devices based on conventional inorganic materials.

Fabrication of electronic devices—whether from organic or inorganic materials—requires the creation on an industrial scale of precisely defined microscopic patterns of the organic or inorganic active materials in these devices. As shown in FIG. 1, this process is accomplished by “photolithography,” in which a microscopic pattern of light and shadow created by shining a light through a photographic mask is used to expose a light-sensitive “photoresist” film that has been deposited on a substrate material of the device (FIG. 1a), thereby changing the chemical properties of the portions of the photoresist that have been exposed to light (FIG. 1b, striped areas in photoresist layer). In a “positive” photoresist, the portions of the photoresist that are exposed to light become soluble in the “developer” solution that is then applied to the exposed photoresist; as a result, the light-exposed portions of the photoresist are washed away (“developed”) by the developer solvent to leave a pattern of unexposed photoresist and newly exposed underlying substrate material which may then be coated with the desired organic material(s). A “negative” photoresist is treated as for a positive photoresist; however, in a negative photoresist, it is the unexposed rather than the exposed portions of the photoresist that are washed away by the developing solvent (FIG. 1c shows the results of development of a negative photoresist). In either case, the application of photoresist to a substrate followed by exposure through a photographic mask results in a latent pattern of developer-soluble and developer-insoluble portions of photoresist (FIG. 1b), where—much as for standard photographic film—this latent pattern becomes manifest by treatment of the exposed photoresist with the appropriate developer to actually remove the portions of the photoresist that are now converted to soluble form (FIG. 1c). At this point, active semiconductor material is deposited on both the substrate (FIG. 1d where photoresist is removed) and on unremoved photoresist (FIG. 1d, remaining areas); in an additional “lift-off” or “stripping” step, remaining photoresist with an overlying layer of active material is removed via the appropriate solvent (FIG. 1e) to leave the desired patterned active material.

Although the use of photoresists is routine in traditional electronic devices based on inorganic materials, photolithography has been difficult to obtain for devices using organic materials, thereby hindering the development of devices based on these materials. Specifically, organic materials are much less resistant to the solvents that are used for conventional photolithography, as well as to the intense light sources that are used in these processes, with the result that conventional lithographic solvents and processes tend to degrade organic electronics. Although there have been various attempts to overcome these problems, e.g., by ink-jet printing or shadow mask deposition, these alterative methods do not produce the same results as would be obtained with successful photolithography. Specifically, neither ink jet printing nor shadow mask deposition can achieve the fine pattern resolutions that can be obtained by conventional lithography, with ink-jet printing limited to resolutions of approximately 10-20 μm and shadow mask deposition to resolutions of about 25-30 μm.

In light of the above, there is a great need for better photolithographic methods for patterning organic materials, and in particular for photoresists and associated solvent systems that can be used to obtain good patterning of organic materials without degradation of these materials or of the complex, multi-layer devices that are fabricated using these materials.

### SUMMARY OF THE INVENTION

The present invention is partially based on the recognition in WO2009/143357 that halogenated solvents and solvent systems containing halogenated solvents are surprisingly non-damaging to the organic materials used in organic electronic devices, and therefore these solvents may serve as the developers and other solvent components of photolithographic systems used with these organic materials.

Thus in embodiment 1, the present invention is directed to a composition comprising a copolymer of a monomer comprising at least one fluoro-containing group and a monomer comprising at least one acid-hydrolyzable ester-containing group, where the copolymer has a content of fluoro-containing groups that provides sufficient solubility in an orthogonal solvent.

In embodiment 2, the present invention is directed to the composition of embodiment 1, where the orthogonal solvent is a halogen-containing orthogonal solvent.

In embodiment 3, the present invention is directed to the composition of embodiment 2, where the halogen-containing orthogonal solvent is a hydrofluoroether (HFE) or a segregated HFE.

In embodiment 4, the present invention is directed to the composition of embodiment 3, where the HFE is selected from the group consisting of Novec™ 7100, Novec™ 7200, Novec™ 7300, Novec™ 7400, Novec™ 7500, and Novec™ 7600.

In embodiment 5, the present invention is directed to the composition of embodiment 2, where the halogen-containing orthogonal solvent further comprises additional non-halogen-containing solvent or solvents.

In embodiment 6, the present invention is directed to the composition of embodiment 5, where the additional non-halogen-containing solvent is isopropyl alcohol (IPA).

In embodiment 7, the present invention is directed to the composition of embodiment 1, where the copolymer has a bulk fluorine content of between 30-50% weight/weight.

In embodiment 8, the present invention is directed to the composition of embodiment 7, where the copolymer has a bulk fluorine content of between 37-45% weight/weight.

In embodiment 9, the present invention is directed to the composition of embodiment 1, where the copolymer has a sufficient content of acid-hydrolyzable ester-containing groups to provide complete insolubility in an orthogonal solvent upon hydrolysis of at least 80% of the hydrolyzable ester-containing groups.

In embodiment 10, the present invention is directed to the composition of embodiment 9, where the orthogonal solvent is a halogen-containing solvent.

In embodiment 11, the present invention is directed to the composition of embodiment 10, where the halogen-containing solvent is a hydrofluoroether (HFE) or a segregated HFE.

In embodiment 12, the present invention is directed to the composition of embodiment 11, where the HFE is selected from the group consisting of Novec™ 7100, Novec™ 7200, Novec™ 7300, Novec™ 7400, Novec™ 7500, and Novec™ 7600.

In embodiment 13, the present invention is directed to the composition of embodiment 10, where the halogen-containing orthogonal solvent further comprises additional non-halogen-containing solvent or solvents.

In embodiment 14, the present invention is directed to the composition of embodiment 13, where the additional non-halogen-containing solvent is IPA.

In embodiment 15, the present invention is directed to the composition of embodiment 1, where the at least one hydrolyzable ester-containing group is selected from the group consisting of a light-stimulated hydrolyzable ester-containing group, a chemically-stimulated hydrolyzable ester-containing group, or a mixture thereof.

In embodiment 16, the present invention is directed to the composition of embodiment 15, where the group is a light-stimulated hydrolyzable ester-containing group.

In embodiment 17, the present invention is directed to the composition of embodiment 16, where the light-stimulation is maximal at 365 nm.

In embodiment 18, the present invention is directed to the composition of embodiment 17, where the group is a chemically-stimulated hydrolyzable ester-containing group.

In embodiment 19, the present invention is directed to the composition of embodiment 18, where the chemical stimulation is via an acid generating compound.

In embodiment 20, the present invention is directed to the composition of embodiment 19, where the acid-generating compound is a photoacid generator (PAG).

In embodiment 21, the present invention is directed to the composition of embodiment 1, where the copolymer is a random copolymer.

In embodiment 22, the present invention is directed to the composition of embodiment 1, where the copolymer is a block copolymer.

In embodiment 23, the present invention is directed to the composition of embodiment 1, where the copolymer further comprises a third monomer.

In embodiment 24, the present invention is directed to the composition of embodiment 23, where the third monomer is a PAG.

In embodiment 25, the present invention is directed to the composition of embodiment 1, where the monomer comprising at least one fluoro-containing group is perfluorodecyl methacrylate (FDMA).

In embodiment 26, the present invention is directed to the composition of embodiment 1, where the monomer comprising at least one fluoro-containing group is perfluorooctyl methacrylate (FOMA).

In embodiment 27, the present invention is directed to the composition of embodiment 26, where the copolymer has a bulk fluorine content of between 37-45% weight/weight.

In embodiment 28, the present invention is directed to the composition of embodiment 26, where the average molecular weight of the bulk copolymer is 35,000.

In embodiment 29, the present invention is directed to the composition of embodiment 26, where the molecular weight distribution is 25,000-38,000.

In embodiment 30, the present invention is directed to the composition of embodiment 26, where the monomer comprising at least one hydrolyzable ester-containing group is 2-nitrobenzyl methacrylate (NBMA).

In embodiment 31, the present invention is directed to the composition of embodiment 26, where the monomer comprising at least one hydrolyzable ester-containing group is tert-butyl methacrylate (TBMA).

In embodiment 32, the present invention is directed to the composition of embodiment 31, where at least 50% of hydrolyzable ester-containing groups in the bulk copolymer are hydrolyzed.

In embodiment 33, the present invention is directed to the composition of embodiment 32, further comprising an organic electronic device substrate, semiconductor, or combinations thereof.

In embodiment 34, the present invention is directed to the composition of embodiment 33, where the organic electronic device substrate or semiconductor are selected from the group consisting of SiO2, plastic, and poly(3,4-ethylenedioxythiophene) poly(styrenesulfonate) (PEDOT:PSS), 6,13-bis(Triisopropylsilylethynyl) (TIPS) pentacene, ruthenium(II) tris(bipyridine) with hexafluorophosphate counter ions ([Ru(bpy)₃]²⁺(PF₆)₂), poly-3-hexylthiophene (P3HT), and polyfluorene, poly(9,9-didecylfluorene-co-benzothiadiazole) (F8BT).

In embodiment 35, the present invention is directed to any of the compositions of embodiments 1-34, further comprising an orthogonal solvent.

In embodiment 36, the present invention is directed to a method of making any of the compositions of embodiments 1-35.

Other advantages and features of the disclosed process will be described in greater detail below. Although only a limited number of embodiments are disclosed herein, different variations will be apparent to those of ordinary skill in the art and are explicitly within the scope of the present invention.

### BRIEF DESCRIPTION OF THE DRAWINGS

The drawings provided in the present invention are provided solely to better illustrate particular embodiments of the present invention, and specifically do not provide an exhaustive or limiting set of embodiments of the present invention.

FIG. 1 provides a schematic of a photolithographic process used to pattern an active material on a substrate material. FIG. 1(a) shows photoresist (purple) deposited on substrate (black). FIG. 1(b) shows the exposure of deposited photoresist to light through a photographic mask with a pattern of black and white (light-opaque and light-transparent) areas to produce unexposed (purple) and exposed (light purple) regions of the photoresist. FIG. 1(c) shows the effect of treatment of exposed photoresist with a “developer” solution; in this case the photoresist is a negative photoresist, so that unexposed photoresist is removed by developer to expose the substrate, while exposed photoresist is resistant to removal by developer, and remains as a pattern covering the substrate. FIG. 1(d) shows active material deposited on the patterned photoresist of FIG. 1(c), while FIG. 1(e) shows the effects of treatment of the device of FIG. 1(d) with “stripper” solution to remove exposed photoresist (shown in blue in FIG. 1(d)) and overlying active material, leaving only active material deposited on the substrate (FIG. 1(e)).

FIG. 2(a) and (b) provides the left and right portions of an NMR spectrum for Applicant's “OSCoR 1000” Polymer, lot # 2011-01-24 in CdCl₃. Integrated peak areas are shown overlaid in red.

FIG. 3 provides Size-Exclusion Chromatography (SEC) data for the FOMA-TBMA photoresist.

FIG. 4 provides quantition of the SEC data of FIG. 3.

FIG. 5 provides a spin curve for FDMA-TBMA.

### DETAILED DESCRIPTION OF THE INVENTION

The present invention is particularly based on the recognition in WO2009/143357 that halogenated solvents and solvent systems containing halogenated solvents are surprisingly non-damaging to the organic materials used in organic electronic devices, and therefore these solvents may serve as the developers and other solvent components of photolithographic systems used with these organic materials.

Thus as described in WO2009/143357 (the contents of which are incorporated in their entirety by reference), there are a number of halogenated solvents and solvent systems containing these halogenated solvents that are non-damaging to organic semiconductors, and can therefore be used in the non-damaging photolithographic patterning of organic semiconductors. Solvents for this purpose include any of the halogenated solvents disclosed in WO2009/143357, and particularly fluorinated solvents such as the hydrofluoroethers (“HFEs”) and particularly the segregated HFEs such as the 3M Novec™ solvents including but not limited to Novec™ 7100, 7200, 7300, 7400, 7500, and 7600 (synonymously HFE-7100, HFE-7200, HFE-7300, etc.), which are advantageous because they have a low “Global Warming Potential” (“GWP”). Suitable solvents also include mixtures containing these halogenated solvents, such as mixtures of the Novec™ solvents and, e.g., isopropyl alcohol (“IPA”), etc. These halogenated solvents (individually, in combination with other such solvents, or in combination with other solvents such as IPA) are collectively termed “orthogonal” solvents for these organic semiconductors because they do not dissolve or damage these organic compounds, as determined by, for example, the ability of organic devices to be immersed in these orthogonal solvents prior to operation without any reduction in functioning. See WO2009/143357 or, e.g., Zakhidov et al. (2008): Adv. Mater. 20:3481-3484. Applicants note that WO2009/143357 also describes the use of supercritical CO₂ (“sCO₂”) as an “orthogonal” solvent, and that the “orthogonal” solvents referred to here explicitly include sCO₂-based solvent systems (as well as all of the other orthogonal solvents described in WO2009/143357 and disclosed elsewhere herein), although halogenated solvent systems and particularly fluorinated solvent systems are preferred.

WO2009/143357 provides data for three photoresists that are compatible with the orthogonal solvents described in WO2009/143357: 1) resorcinarene, which is disclosed as being used in HFE (specifically, spin-coated from HFE-7500+PGMEA (p. 21, paragraph 93) and developed in HFE-7200+rinsed in HFE-7300 (p. 21, paragraph 94) and then stripped in HFE (type not specified)+hexamethyldisilazane (“HMDS”)); 2) “FDMA-NBMA” (a random copolymer of perfluorodecyl methacrylate-2-nitrobenzyl methacrylate), which is disclosed as being used in HFE (specifically, spin-coated from HFE-7600 and developed in HFE-7200 (p. 23, paragraph 98) and stripped in HFE-7100+2-propanol (page 27, paragraph 111)); and, 3) “FDMA-TBMA” (a random copolymer of perfluorodecyl methacrylate-tert-butyl methacrylate), which is disclosed as being used in sCO₂ (development in sCO₂ and stripping in sCO₂+HMDS (page 32, paragraph 124)). Although these photoresists can be used to pattern organic semiconductors, they are not optimized for use in commercial-scale resist production. Thus, for example, resorcinarene-based resists are extremely expensive to synthesize; FDMA-based copolymers, while relatively inexpensive, involve syntheses that require chemical precursors that are being discontinued from commercial production because they can generate the dangerous and highly regulated compound perfluorooctanoic acid (“PFOA”) (see epa.gov/opptintr/pfoa/).

Although the present invention explicitly includes the use of the solvent systems and photoresists of WO2009/143357, it is preferentially drawn to the use of new photoresists developed to overcome some of the limitations of the WO2009/143357 resorcinarene, FDMA-NBMA and FDMA-TBMA photoresists discussed above. Specifically, the present invention is preferably drawn to the use of photoresists such as (but not limited to) FOMA-(perfluorooctyl methacrylate) based copolymers, including (but not limited to), FOMA copolymerized with either NBMA or TBMA, i.e., FOMA-NBMA or FOMA-TBMA random copolymers and block copolymers. In addition to their relatively low cost of synthesis and avoidance of PFOA generation, these photoresists are also maximally adapted for use with the particular orthogonal solvent systems of the present invention, and have other advantageous properties that are described below.

Thus in one preferred aspect, the present invention is drawn to photoresists that are preferably FOMA-based copolymers, including both light-sensitive (non chemically-amplified) FOMA-based copolymers such as FOMA-NBMA random copolymers and block copolymers and chemically-amplified (PAG-requiring) FOMA-based random and block copolymers such as FOMA-TBMA random and block copolymers. Applicants note that “FOMA-NBMA” refers to a polymer of FOMA and NBMA monomers, i.e., could be alternately stated as “poly (FOMA-NBMA)” or “P(FOMA-NBMA),” and that “FOMA-NBMA” explicitly includes varying bulk ratios of FOMA/NBMA monomers as well as random and block copolymers of FOMA and NBMA. This terminology also applies to “FOMA-TBMA” and, generally, to any polymers given in the present application in this “monomer X-monomer Y” form.

In addition to the previously described advantages of these photoresists of low synthesis cost and avoidance of PFOA generation, these photoresists have other advantageous properties such as: 1) good solubility in the orthogonal solvents of the present invention, particularly the preferred HFEs of the present invention; 2) good film forming abilities; 3) good adhesion to a variety of substrates; 4) high glass transition temperature (Tg); 4) good light sensitivity (for light-sensitive photoresists such as FOMA-NBMA); 5) good high-resolution patterning; 6) good sidewall formation; and, 7) good solubility in stripper.

### Solubility in Orthogonal Solvents

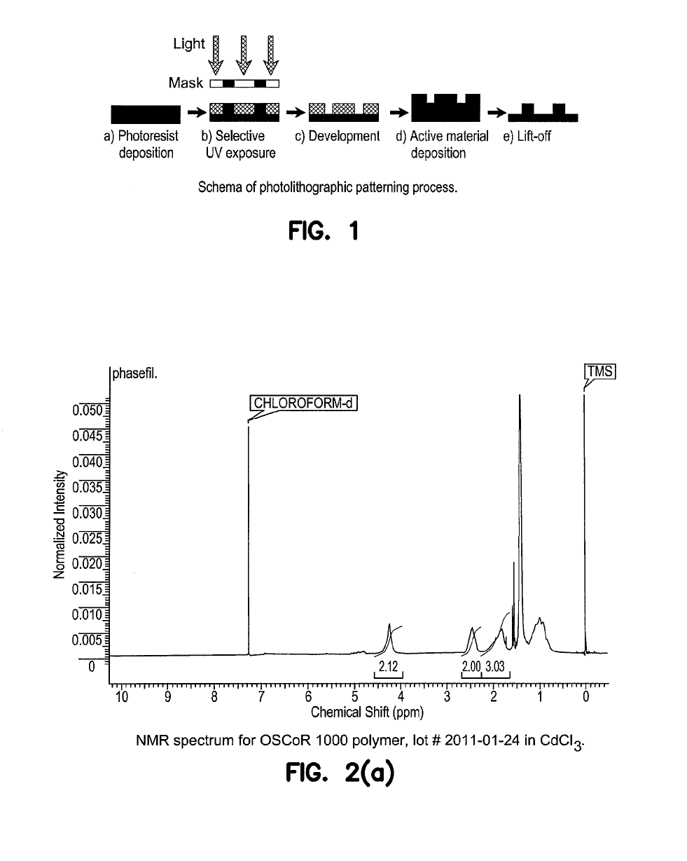

With regard to solubility in orthogonal solvent, the complete photolithographic process shown in FIG. 1 involves the use of at least three orthogonal solvents: a) deposition solvent, which is the solvent in which the photoresist is dissolved for deposition on substrate by, e.g., spin coating; b) developer, which is used to develop the latent pattern of photoresist produced by light-exposure, i.e., to remove soluble resist created for a positive photoresist by exposure to light or, for a negative photoresist, by the absence of exposure to light; and, c) stripper, which is a harsher solvent than developer, and is used to strip exposed photoresist after active material is applied (see, e.g., FIG. 1e). Therefore, “solubility in orthogonal solvent” (or “sufficient solubility in an orthogonal solvent”) refers to a matched set of solubilities in all three of the deposition, developer and stripper solvents, not to a single solubility property.

Specifically, photoresist that has not been exposed to light (for a light-sensitive photoresist) or to light-generated acid (for a chemically-amplified photoresist) must be highly soluble in deposition solution, in order that deposition of sufficient photoresist can be accomplished. For developer, a positive photoresist must be highly soluble in developer if light- or photoacid-exposed, and highly insoluble in developer if not light- or photoacid-exposed; for a negative photoresist, the solubilities are reversed (soluble if unexposed; insoluble if exposed). For stripper, the least soluble form of the photoresist must be sufficiently soluble in stripper that it will be completely removed by stripping, where stripper harshness and length of stripping are constrained by the requirement that stripping not damage the organic electronics, i.e., that the stripper work under conditions where it remains an orthogonal solvent for the organic electronics being used. Therefore, photoresist will ideally be optimized for its properties in all three of these orthogonal solvents (deposition solvent, developer, and stripper).

The photoresists of the present invention, including particularly the FOMA-based photoresists of the present invention, have been optimized for their properties in all three orthogonal solvents. Thus for example the resorcinarene of WO2009/143357 is soluble in the HFE-7500 deposition solvent only when a small amount of propylene glycol methyl ether acetate (PGMEA) is added, a situation that is not desirable because of the requirement for this mixed system of HFE and PGMEA. Furthermore, both the resorcinarene and FDMA-TBMA of WO2009/143357 require a HMDS-resolubilization step prior to stripping, which is again undesirable because it entails an extra stage of processing in the production of the organic electronic device. In contrast, the photoresists of the present invention do not require PGMEA or resolubilization in HMDS. See, e.g., Example 3, which is directed to the FOMA-TBMA photoresist of the present invention.

### Film Forming Ability and Adhesion to Substrate

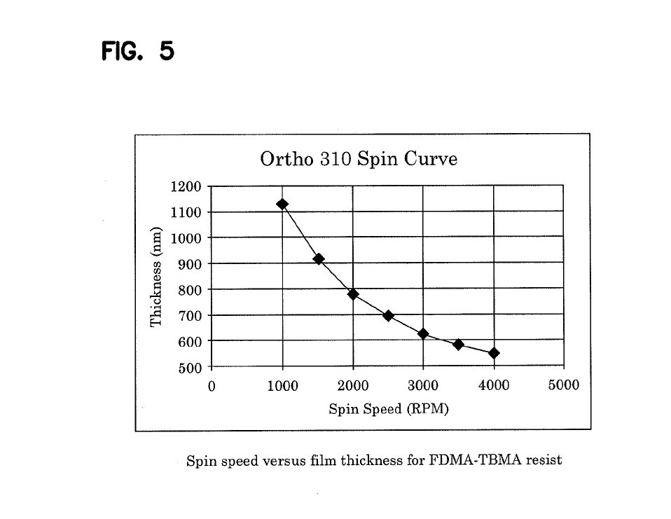

In order for a photoresist to be useful, it must form a film of sufficient thickness (e.g. >300 nm) with low thickness variation (e.g., <±10%) across the substrate on which it has been spin coated. It must also adhere to a variety of substrates including not just SiO₂ and plastic but also, e.g., poly(3,4-ethylenedioxythiophene) poly(styrenesulfonate) (PEDOT:PSS). The photoresists of the present invention provide these film forming and adhesion properties; FIG. 5, for example, provides data on film thickness formed as a function of spin coating speed, and demonstrates the ability to form films of >300 nm thickness.

### Tg, Light Sensitivity, High-Resolution Patterning, Sidewall Formation

Applicants note that there are a number of other factors that affect photoresist performance, and that the photoresists of the present invention have been designed to satisfy these performance criteria. Glass transition temperature (“Tg”), for example, has been designed to be relatively high, in order to prevent poor sidewall profiles and distorted features in the final film caused plasticizing and deformation of the photoresist during the post-spin and post-exposure bake steps (see Example 3).

With regard to light sensitivity, the light used to expose resist patterns on commercial tools used for LCD manufacturing, comes from a mercury arc lamp with peaks at 436 nm, 405 nm and 365 nm (g-line, h-line and i-line). For advanced silicon fabrication, deep UV with a wavelength of 193 nm is preferred. For the present invention, i-line (365 nm) irradiation is preferred. Therefore, chemically-amplified photoresists of the present invention (e.g., FOMA-TBMA) have been optimized for use with PAGs of the requisite light sensitivity, while non-chemically amplified photoresists of the present invention (e.g., FOMA-NBMA) have been designed to inherently possess the requisite light sensitivity.

Further with regard to PAGs, the present invention contemplates the use of any PAG with the appropriate light sensitivity and yield of photoacid, including, but not limited to, any of the PAGs disclosed in WO2009/143357. Examples 1-3 provide the use of the exemplary CIBA/BASF PAG CGI-1907.

With regard to sidewall shape, liftoff patterning of materials requires vertical or undercut sidewalls; if, on the other hand, the sidewalls slope outwards, then continuous films of deposited material will form between the bottom of the pattern and the top of the resist, making it difficult to make a clean break in the film and possibly leading to jagged edges and delaminated films. There are a number of issues that can lead to poor sidewall profiles, including low Tg, PAG migration at the surface during post exposure baking and back reflections from the substrate. The photoresists of the present invention have been designed to minimize these problems.

### Solubility in Stripper

Suitable photoresists must be highly soluble in the orthogonal deposition solvent, soluble/insoluble (depending upon light or photoacid exposure) in the orthogonal developer solvent, and highly soluble (regardless of light or photoacid exposure) in the orthogonal stripping solvent; as already discussed, the photoresists of the present invention have been optimized for these parameters without requiring, e.g., PGMEA or resolubilization post-exposure in, e.g., HMDS.

More generally, the present photoresists have been designed to contain the appropriate monomer ratios and bulk fluorine content to satisfy these solubility/insolubility requirements. Thus Applicants data suggest that certain monomer ratios and bulk fluorine content(s) are important for achieving these performance criteria, possibly because the balance between fluorine content (which contributes to solubility in the orthogonal solvents of the present invention) and acid- or light-sensitive monomer group (e.g., TBMA or NBMA) (which contribute the solubility-switching acid-hydrolyzable ester-containing group(s)) critically affects these criteria, although Applicants are not bound to any particular theory regarding functionality. Therefore, in some embodiments of the present invention, Applicants have explicitly defined the appropriate monomer ratio and/or bulk fluorine content of the photoresist(s) to be used.

### Photoresist Properties On Substrate

The present invention uses both non-chemically-amplified and chemically-amplified photoresists in combination with the orthogonal solvents of the invention for the photolithographic patterning of organic electronic devices. For example, two non-limiting examples of the FOMA-derived photoresists of the present invention can be, e.g., FOMA-NBMA (non-chemically-amplified) and FOMA-TBMA (chemically-amplified). For non-chemically-amplified/chemically-amplified photoresist sets such as FOMA-NBMA/FOMA-TBMA the insoluble acid form of the photoresist is the same in either case, i.e., is the—methacrylic acid (“—MA”) form which results when either—NBMA or—TBMA is converted to—MA.

Thus one aspect of the present invention is drawn to the insoluble (in this case the—MA form) of the photoresist(s) of the invention as this form exists on the substrate on which the photoresist has been exposed, irradiated, and developed.

With regard to photoresists of the present invention providing this—MA form, Applicants note that either non-chemically-amplified photoresists or chemically-amplified photoresists may not require complete cleavage of every potentially cleavable monomer in order to become sufficiently insoluble to allow for patterning; thus for example although Applicants represent the insoluble form of FOMA-NBMA or FOMA-TBMA generically as “FOMA-MA,” in fact “FOMA-MA” will strictly be a polymer with some FOMA content, some MA content, and potentially some residual uncleaved NBMA or TBMA content (e.g., 0%, 1%, 2%, . . . , counting by 1% increments), since 100% conversion of NBMA or TBMA to MA is not required to obtain insolubility in the orthogonal developer used. Thus “FOMA-MA” refers generically to the form of the FOMA-derived photoresist of the invention where a sufficient number of cleavable monomer units (e.g., NBMA or TBMA monomer units) have been cleaved so that good patterning is obtained—i.e., “FOMA-MA” is typically functionally defined, although of course specific % cleavage may also be given.

The following are non-limiting examples of some of the various embodiments of the present invention.

### EXAMPLE 1

### Preparation of FOMA-TBMA Photoresist

A solution of 110.10 g (0.7743 mol.) of tert-butyl methacrylate, (TBMA), 330.07 g (0.7636 mol.) of 1H,1H,2H,2H-perfluorooctyl methacrylate, (“FOMA”), 874.2 g of Novec 7600 and 5.51 g (0.0335 mol.) of azobisisobutyronitrile, (“AIBN”) was stirred in a jacketed reaction flask. The flask jacket was connected to a programmable, constant temperature bath (“CTB”) capable of heating and maintaining a set jacket temperature. The solution was sparged with nitrogen at a rate of 0.5 L/minute for 1 hour at ambient temperature. A CTB program was initiated which heated the reaction jacket to 68° C., holds this temperature for 1 hour, heats to 72° C. and holds for 1 hour, and finally heats to 76° C. and holds for 12 hours. When the heating program was completed, the CTB was set to cool the reaction mixture to ambient temperature. The clear, colorless polymer solution obtained was diluted to a viscosity by the addition of 3.714 kg of Novec™ 7600, and a small sample was removed and dried under vacuum for later characterization (see below). Under yellow lights, 22.0 g of CIBA/BASF CGI-1907 photo acid generator (“PAG”) (5% by weight of the original dry weight of TBMA) was dissolved in the remaining photoresist solution. The solution was filtered, and was then ready for use.

### EXAMPLE 2

### Characterization of FOMA-TBMA Photoresist

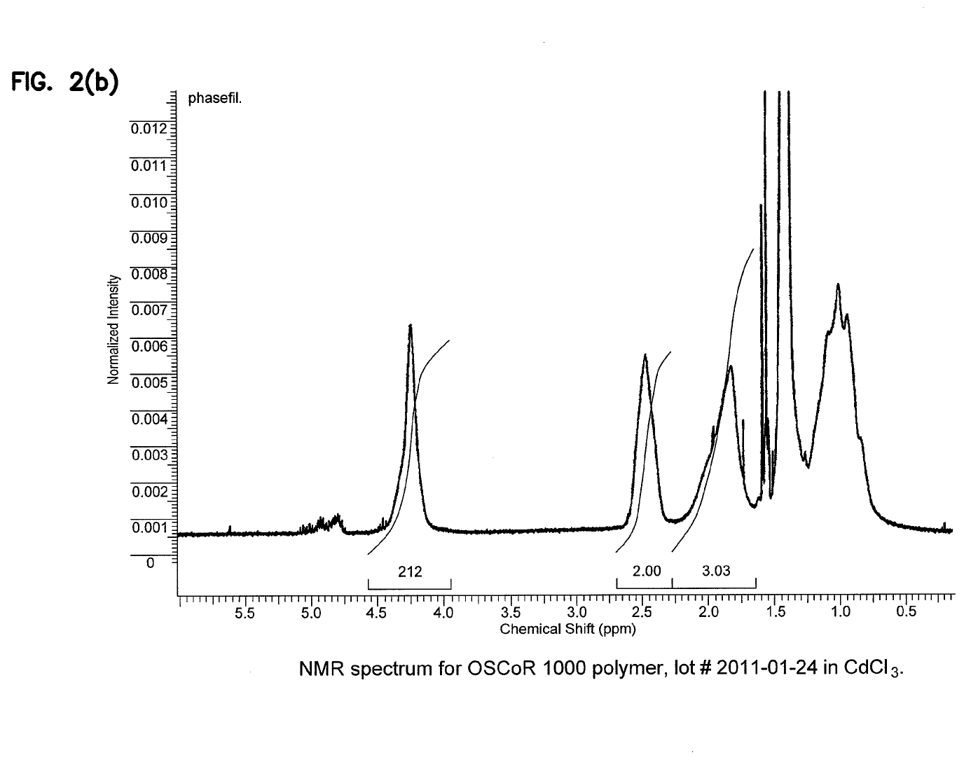

Proton NMR was performed on the photoresist sample obtained from Example 1 resuspended in deuterated chloroform (CdCl₃), with the resulting spectrum obtained from this sample shown in FIGS. 2(a) and 2(b). In this spectrum, the broad peak centered at 2.5 ppm arises from the methylene group adjacent to the perfluoroalkyl chain in the FOMA, while the broad peak centered at 1.7 ppm arises from the TBMA methyl group in the polymer backbone. Proton integration (red overlay) of these peaks was used to calculate a mole ratio of the monomers in the photoresist polymer as FOMA/TBMA: 1.00/1.01, which closely matches the input (feed) FOMA/TBMA monomer ratio of 1.000/1.014.

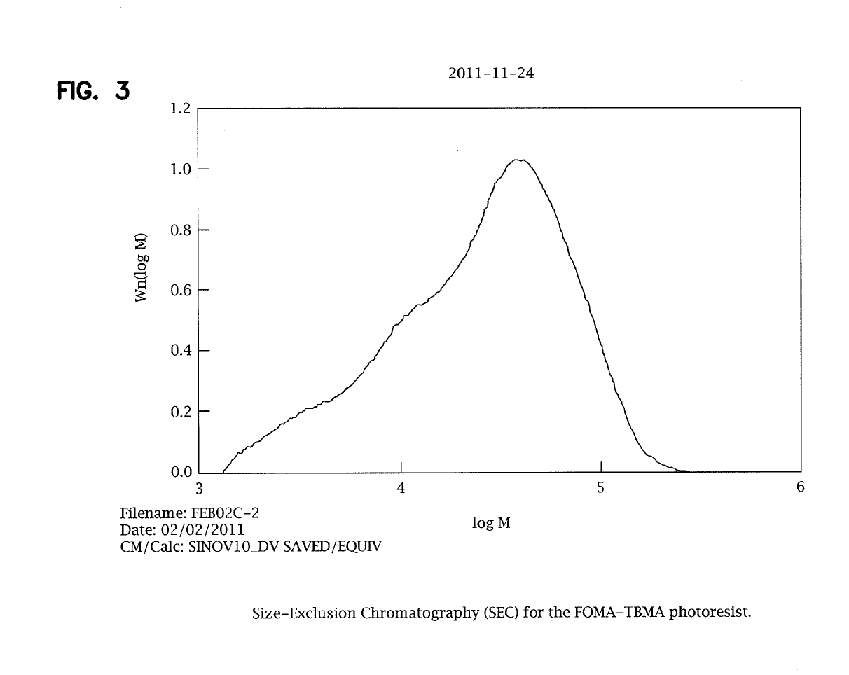

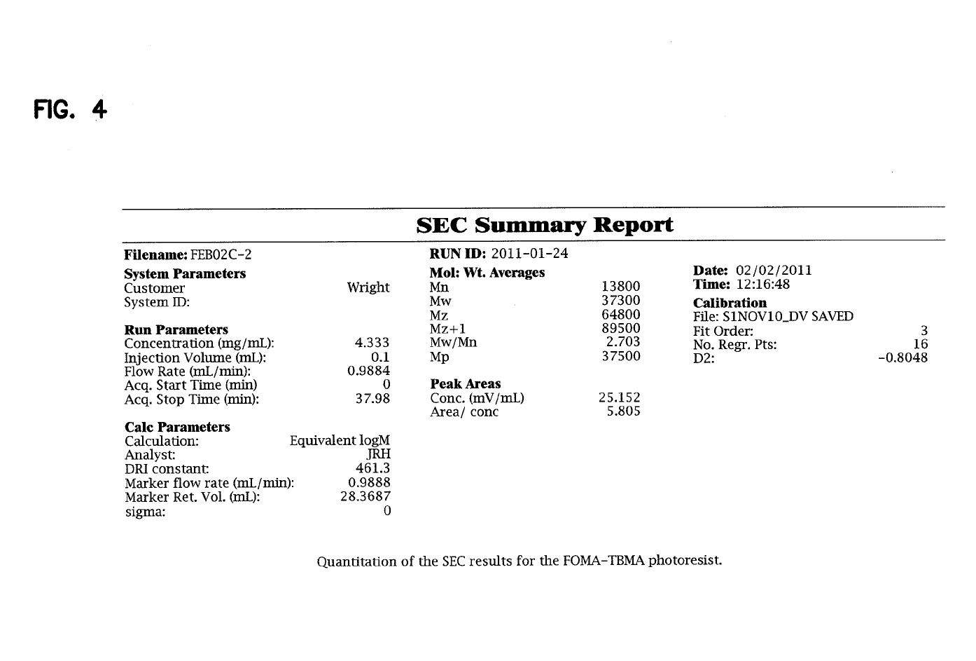

In order to determine the size distribution of the photoresist polymer, size-exclusion chromatography (SEC) was performed, as is shown in FIGS. 3 and 4, yielding a weight-averaged molecular weight of Mw=37,300. Glass transition temperature analyses were also performed, with the following results: start temperature=44.7° C., final temperature=59.9° C., temperature range=15.2° C., Tg=53.4° C.

### EXAMPLE 3

### Patterning of FOMA-TBMA Photoresist

PAG-containing FOMA-TBMA photoresist prepared as described in Example 1 was deposited on substrate using spin coating. Specifically, spin coating was performed with a static dispense method, where photoresist was placed on a non-spinning wafer and the wafer was rapidly (<2 seconds) brought up to full rotational speed. Spin coating in all cases was done for 60 seconds with a covered spin coater (Cee Processing equipment from Brewer Science) in a fume hood to control airflow and particle contamination. Films were measured with a FilMetrics F50 thickness mapping tool, using index values measured on a Woolam Elipsometer. FIG. 5 provides a spin curve for FDMA-TBMA.

After spin-coating, the coated substrate was baked at 90° C. for 1 minute.

The coated substrate was then exposed to 365 nm (“I-line”) light, typically in a dose range of between 50 and 80 mJ/cm², and then subjected to a post-exposure bake (“PEB”) step. For a 75° C. PEB, the preferred exposure for FOMA-TBMA-containing 5% PAG (CGI-1907) was 77 mJ/cm². For PAG concentrations other than 5% CGI-1907, the following table shows the observed relationship between PEB temperature, PAG concentration and target dose:

| PEB Temp. | PAG | 2% | 1% | 0.5% |
|---|---|---|---|---|
| 75° C. | | 293 mJ/cm² | 470 mJ/cm² | 508 mJ/cm² |
| 90° C. | | 85 mJ/cm² | 231 mJ/cm² | 323 mJ/cm² |
| 115° C. | | 31 mJ/cm² | 123 mJ/cm² | 169 mJ/cm² |
| 130° C. | | 15 mJ/cm² | 69 mJ/cm² | 108 mJ/cm² |

After PEB, the latent pattern in the exposed photoresist was developed using the appropriate developer, typically Novec™ 7300. This developer would appear to be suboptimal, in that it has a slower development time than other “stronger” solvents such as Novec™ 7200; however, Applicants have observed that —surprisingly—a weaker solvent such as Novec™ 7300 is actually advantageous because a longer development time allows for better process control, and a weaker developer is less prone to over-development than stronger developers. Applicants note that for particular substrates such as PEDOT:PSS, strong solvents such as Novec™ 7600 are preferred because—despite their harshness—they are still sufficiently orthogonal to the substrate but are more effective at removing unexposed FOMA-TBMA.

Once the exposed photoresist has been developed, active material is then deposited and, after deposition, remaining photoresist (with an overlayer of active material) is then removed via a “stripping” step. Deposition of active material may be performed by any of the common methods known in the art for such deposition, see, e.g., WO2009/143357 or, e.g., Zakhidov et al. (2008): Adv. Mater. 20:3481-3484. Stripping is performed using the appropriate stripping solvent, with the choice of solvent dependent on the extent of exposure of the photoresist. Two preferred strippers are: “strong” stripper, which is Novec™ 7200 +10% by volume isopropyl alcohol (“IPA”); and, “weak” stripper, which is Novec™ 7600. Applicants have optimized weak stripper for use with materials that are damaged by either the Novec™ 7200 or IPA components of strong stripper; weak stripper is, however, less generally applicable to a variety of commercial production processes than is strong stripper.

The following claims provide a non-limiting list of some of the embodiments of the present invention.

1.-35. (canceled)

36. A composition comprising a halogen-containing solvent, a photoacid generator compound and a copolymer of a monomer comprising at least one fluoro-containing group and a monomer comprising at least one acid-hydrolyzable ester-containing group.

37. The composition of claim 36, where the halogen-containing solvent is a hydrofluoroether (HFE) or a segregated HFE.

38. The composition of claim 36, where the halogen-containing orthogonal solvent further comprises additional non-halogen-containing solvent or solvents.

39. The composition of claim 38, where the additional non-halogen-containing solvent is isopropyl alcohol (IPA).

40. The composition of claim 36, where the copolymer has a bulk fluorine content of between 30-50% weight/weight.

41. The composition of claim 40, where the copolymer has a bulk fluorine content of between 37-45% weight/weight.

42. The composition of claim 36, where the copolymer is a random copolymer.

43. The composition of claim 36, where the copolymer is a block copolymer.

44. The composition of claim 36, where the copolymer further comprises a third monomer.

45. The composition of claim 44, where the third monomer includes the photoacid generator compound.

46. The composition of claim 36, where the monomer comprising at least one fluoro-containing group is perfluorooctyl methacrylate (FOMA).

47. The composition of claim 46, where the copolymer has a bulk fluorine content of between 37-45% weight/weight.

48. The composition of claim 46, where the molecular weight distribution is 25,000-38,000.

49. The composition of claim 46, where the monomer comprising at least one hydrolyzable ester-containing group is tert-butyl methacrylate (TBMA).

50. A method of patterning a negative photoresist, comprising:
forming layer of a photoresist by coating a photosensitive composition comprising a halogen-containing solvent, a photoacid generator compound and a copolymer of a monomer comprising at least one fluoro-containing group and a monomer comprising at least one acid-hydrolyzable ester-containing group;
exposing the layer of photoresist to patterned light;
developing the photoresist by contact with a developing solvent comprising a hydrofluoroether or segregated hydrofluoroether to remove unexposed portions of the photoresist, thereby forming a patterned photoresist.

51. The method of claim 36 wherein the halogen-containing solvent is a hydrofluoroether (HFE) or a segregated HFE.

52. The method of claim 36 wherein the copolymer has a bulk fluorine content of between 30-50% weight/weight.

53. The method of claim 32 wherein the copolymer has a bulk fluorine content of between 37-45% weight/weight.

54. The method of claim 36 wherein the copolymer further comprises a third monomer.

55. The method of claim 36 wherein the third monomer includes the photoacid generator compound.
